(19) United States
(12) Patent Application Publication
(10) Pub. No.: US 2007/0190688 A1
(43) Pub. Date: Aug. 16, 2007

(54) METHOD FOR MANUFACTURING SEMICONDUCTOR DEVICE WITH PROTECTION LAYER

(75) Inventors: Han-Shin YOUN, Chungcheongnam (KR); Seung-Kon MOK, Gyeonggi-do (KR); Young-Doo JUNG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggid-do (KR)

(21) Appl. No.: 11/565,901

(22) Filed: Dec. 1, 2006

(30) Foreign Application Priority Data
Feb. 16, 2006 (KR) 2006-0015214

(51) Int. Cl. H01L 21/00

(52) U.S. Cl. 438/108

(57) ABSTRACT

A method for manufacturing a semiconductor device may comprise preparing a wafer having a front surface and a back surface. The wafer may have a plurality of semiconductor chips and scribe lines between the adjacent semiconductor chips. The wafer may be sawn along the scribe lines to form grooves between the adjacent semiconductor chips. A liquid protection material may be screen printed or spin-coated to form a protection layer on the back surface and within the grooves. The protection layer within the grooves may be more narrowly cut to form individual semiconductor devices and to leave a protection layer remaining thereon.

### PRIORITY STATEMENT

This U.S. non-provisional application claims benefit of priority under 35 U.S.C. §119 of Korean Patent Application No. 2006-15214, filed on Feb. 16, 2006, the entire contents of which are incorporated herein by reference.

### BACKGROUND

The present invention relates to a semiconductor manufacturing technique, and more particularly, to a method for manufacturing a semiconductor device with a protection layer.

### DESCRIPTION OF THE RELATED ART

Generally, a semiconductor package manufacturing process may include a wafer fabrication process, a package assembly process and a test process. The wafer fabrication process may create circuits or devices in or on a wafer, i.e., a circular plate of semiconductor materials. The wafer may be sawn into individual semiconductor chips. The package assembly process may produce a semiconductor package using the semiconductor chip.

A wafer level package (WLP) technique has been introduced to manufacture a semiconductor package at wafer level. In other words, package structures are formed on the wafer prior to dividing the wafer into individual semiconductor chips. The WLP technique may provide a chip size package using a conventional wafer manufacturing apparatus and process.

Because a wafer may be divided into semiconductor chips and/or WLPs, semiconductor chips and WLPs are hereinafter commonly referred to as semiconductor devices.

The semiconductor devices, e.g., WLPs; semiconductor chips flip chip bonded to a wiring substrate; and semiconductor chips wire bonded for board-on-chip application may have a side surface and a back surface exposed to external environments. Such exposed surfaces may be susceptible to external shocks.

A protection layer may be formed on a back surface of a semiconductor chip. The protection layer may protect the back surface from external shocks, but not the side surface.

One solution may be to form a protection layer on a side surface of a semiconductor chip. For example, grooves between adjacent semiconductor chips of a wafer may be formed and a liquid protection material may be provided in the grooves using a dispensing method to form a protection layer. The wafer may be sawn along the protection layer in the grooves, thereby forming individual semiconductor devices having each protection layer formed on a side surface. The protection layer may be formed on a back surface as well as a side surface of a semiconductor chip. For example, after a protection layer is formed on a back surface, a protection layer may be formed on a side surface in the same manner as the previous process. Although the conventional art is generally thought to provide acceptable performance, it is not without shortcomings. For example, a dispensing method may require much time to fill a plurality of grooves with a liquid protection material. As the diameter of a wafer increases and thus the number of semiconductor chips increases, dispensing areas may increase, thus increasing the duration of a dispensing process. Further, a protection layer for a back surface and a protection layer for a side surface may be formed separately, thereby resulting in a complicated and time consuming process.

### SUMMARY

An example embodiment of the present invention is directed to protecting a side surface and a back surface of a semiconductor chip from external shocks.

Another example embodiment of the present invention is directed to forming a protection layer on a side surface and a back surface of a semiconductor chip using a single process.

### BRIEF DESCRIPTION OF THE DRAWINGS

The example embodiments of the present invention will be readily understood with reference to the following detailed description thereof provided in conjunction with the accompanying drawings, wherein like reference numerals designate like structural elements.

FIG. 1 is a flow chart of a method for manufacturing a semiconductor device in accordance with an example embodiment of the present invention.

FIGS. 2 through 8 are views of each step of the method for manufacturing a semiconductor device of FIG. 1.

FIG. 9 is a cross-sectional view of another example of a semiconductor device manufactured by the method of FIG. 1.

FIG. 10 is a cross-sectional view of a semiconductor package using the semiconductor device of FIG. 9.

These drawings are provided for illustrative purposes only and are not drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example embodiments of the invention.

### DETAILED DESCRIPTION OF THE EXAMPLE EMBODIMENTS

Example, non-limiting embodiments of the present invention will now be described more fully hereinafter with reference to the accompanying drawings. This invention may, however, be embodied in many different forms and should not be construed as limited to the example embodiments set forth herein. Rather, the disclosed embodiments are provided to make this disclosure thorough, complete, and fully convey the scope of the invention to those skilled in the art. The principles and features of this invention may be employed in varied and numerous embodiments without departing from the scope of the invention.

It should be noted that the figures are intended to illustrate the general characteristics of methods and devices of example embodiments of this invention, for the purpose of the descriptions of such example embodiments herein. These drawings are not, however, to scale and may not precisely reflect the characteristics of any given embodiment, and should not be interpreted as defining or limiting the range of values or properties of example embodiments within the scope of this invention. Rather, for simplicity and clarity of illustration, the dimensions of some of the elements are exaggerated relative to other elements.

Further, well-known structures and processes are not described or illustrated in detail to avoid obscuring the present invention. Like reference numerals are used for like and corresponding parts of the various drawings.

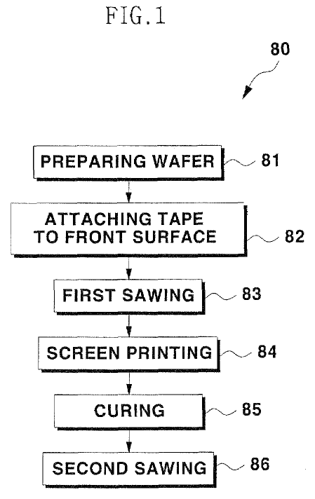

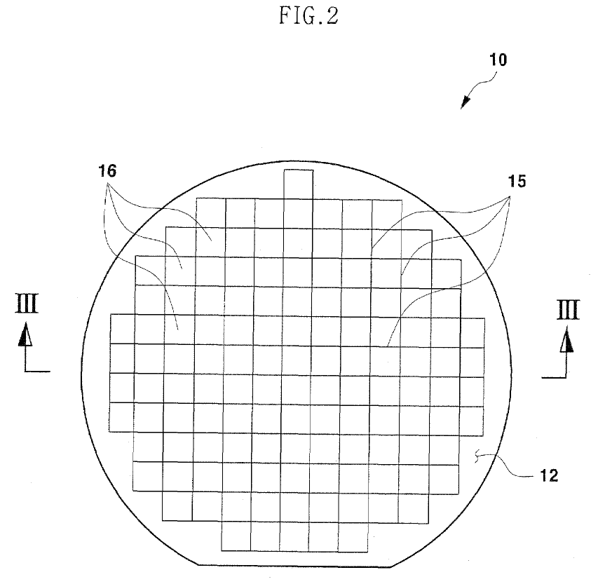

FIG. 1 is a flow chart of a method 80 for manufacturing a semiconductor device in accordance with an example embodiment of the present invention. FIGS. 2 through 8 are views of each step of the method for manufacturing a semiconductor device of FIG. 1.

With reference to FIGS. 1 through 8, the method 80 may begin with preparing a wafer 10 (step 81 of FIG. 1). The wafer 10 may comprise a silicon substrate and integrated circuits formed on or in the substrate through a wafer fabrication process. The integrated circuits may incorporate semiconductor chips 16. Scribe lines 15 may be formed between the adjacent semiconductor chips 16. Because the details of forming the integrated circuits of chips 16 are not essential to an understanding of the present invention, a more detailed description thereof is omitted.

The semiconductor chip 16 may have a front surface 12 and a back surface 13. External connection terminals 17 may be provided on the front surface 12 and include solder balls, solder bumps, Au bumps and Ni bumps. The external connection terminal 17 may be formed directly on a chip pad (not shown) or a redistribution pad (not shown).

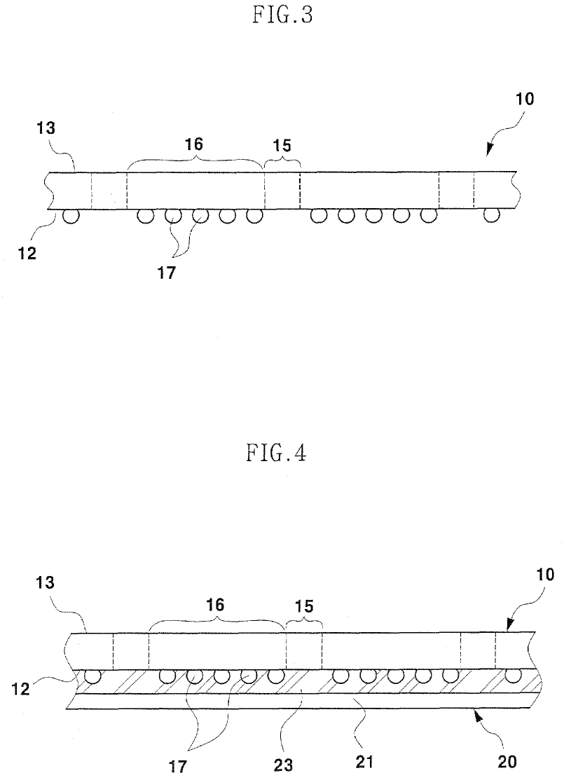

The wafer 10 may be cut along the scribe lines 15 of the front surface 12 at a predetermined depth. For example, the wafer 10 may be “half-cut.” For example, with an expanding tape attached to the back surface 13 of the wafer 10, the wafer 10 may be cut along the scribe lines 15 of the front surface 12 at a predetermined depth using, for example, a half-cutting method. In alternative embodiments, with the back surface 13 of the wafer 10 supported by suction, the wafer 10 may be cut along the scribe lines 15 of the front surface 12 at a predetermined depth using, for example, a half-cutting method. Referring to FIG. 4, a tape 20 may be attached to the front surface 12 of the wafer 10 (step 82 of FIG. 1).

The tape 20 may comprise a base film 21 and an adhesive layer 23 provided on the base film 21. The adhesive layer 23 may be formed of sufficient thickness to cover the external connection terminals 17. The adhesive layer 23 may be formed from materials removable using heat or UV rays, for example a thermoplastic adhesive or a UV adhesive.

If the wafer 10 has not yet undergone a backlapping process, if desired a portion of the back surface 13 of the wafer 10 may be removed after attaching the tape 20. A backlapping process may include a grinding method, an etching method, and a chemical mechanical polishing method.

Referring to FIG. 5, a first sawing process may be performed (step 83 of FIG. 1). The wafer 10 may be sawn into the individual semiconductor chips 16 along the scribe lines 15 using a first sawing blade 31. Grooves 18 may be thereby formed between the adjacent semiconductor chips 16. The semiconductor chip 16 may have a side surface 14 exposed through the groove 18. The first sawing process may be performed on the back surface 13 of the wafer 10.

Although this example embodiment shows a sawing method implemented with a sawing blade 31, the sawing method may use laser or water.

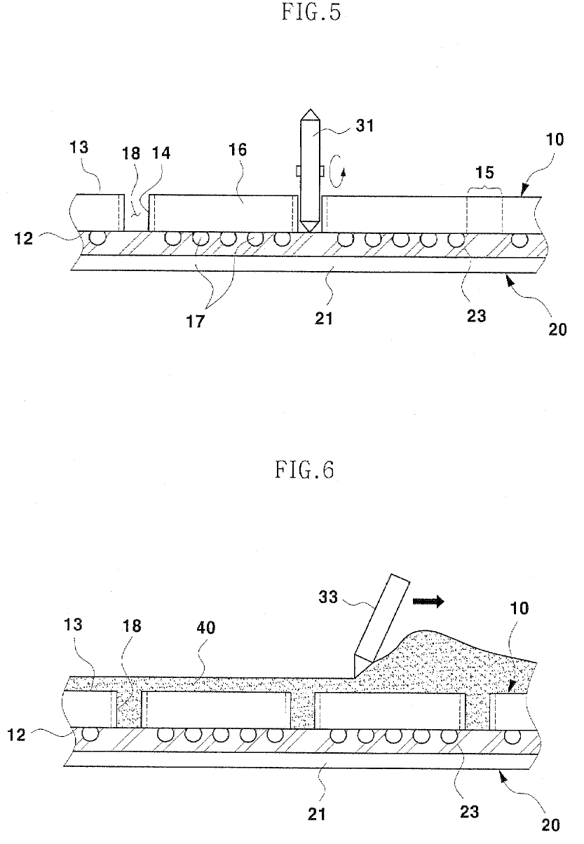

Referring to FIG. 6, a screen-printing process may be performed (step 84 of FIG. 1). A liquid protection material may be provided on the back surface 13 of the wafer 10 and screen-printed using a squeezer 33. A protection layer 40 is thereby formed on the back surface 13 of the wafer 10 including filling the grooves 18 with liquid protection material. The protection layer 40 may be formed from an insulating epoxy resin or a silicon based resin. The protection material may have sufficient viscosity to fill the grooves 18 by screen-printing. The protection material may be provided as liquid or B-stage material.

The screen-printing may fill the grooves 18 with the protection material at the same time, thereby allowing a quick process substantially independent of the diameter of the wafer 10 and/or the size of the semiconductor chip 16. The screen-printing may also form the protection layer 40 on the back surface 13 and the side surface 14 of the semiconductor chip 16 simultaneously, thereby reducing the process time.

The protection layer 40 may be cured (85 of FIG. 1) for attachment. A curing method may include a heat curing method or a UV curing method according to materials of the protection layer 40.

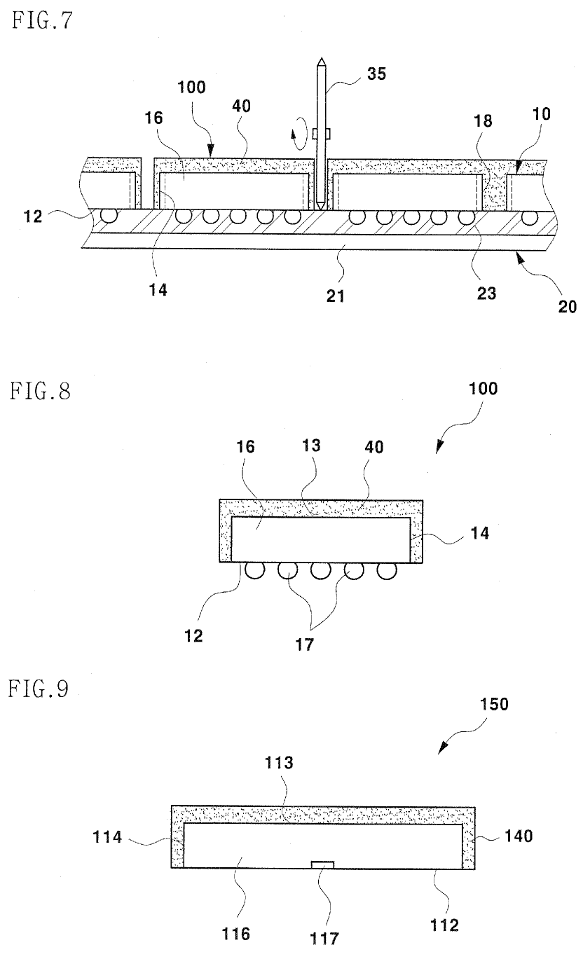

Referring to FIG. 7, a second sawing process may be performed (86 of FIG. 1). The wafer 10 may be sawn into individual semiconductor devices 100, each with protection layer 40 along the protection layer 40 in the grooves 18 using a second sawing blade 35. The protection layer 40 remains attached to the back surface 13 and the side surface 14. The width of the second sawing blade 35 may be smaller than the width of the first sawing blade 31 to leave after the second sawing a portion of the protection layer 40 on the side surface 14.

Although this example embodiment shows a second sawing method implemented with a sawing blade, the second sawing method may use laser or water.

The tape 20 may be irradiated with heat or UV rays for removal thereof. The resulting semiconductor device 100, for example a wafer level package, may be completed as shown in FIG. 8. The semiconductor device 100 may comprise a semiconductor chip 16 having a front surface 12, a back surface 13 and a side surface 14, and a protection layer 40 provided on the back surface 13 and the side surface 14 of the semiconductor chip 16. External connection terminals 17 may be provided on the front surface 12 of the semiconductor chip 16.

Although this example embodiment shows a wafer level package as the semiconductor device 100, a semiconductor device manufactured according to the method of the present invention may be not limited in this regard.

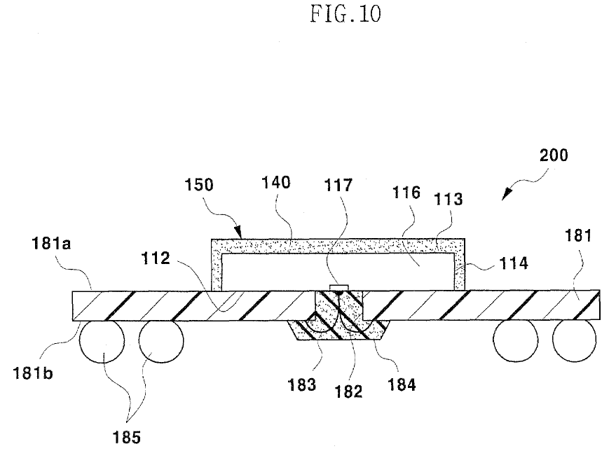

FIG. 9 is a cross-sectional view of another example of a semiconductor device manufactured by the method of FIG. 1.

Referring to FIG. 9, a semiconductor device 150 may comprise a semiconductor chip 116 having a front surface 112, a back surface 113 and a side surface 114, and a protection layer 140 provided on the back surface 113 and the side surface 114 of the semiconductor chip 116. The semiconductor chip 116 may be a center-pad type semiconductor chip where chip pads 117 may be arranged in the center of the front surface 12. Because the protection layer 140 is formed in the same manner as the method of FIGS. 2 through 7, a detailed description is omitted.

FIG. 10 is a cross-sectional view of a semiconductor package 200 using the semiconductor device 150 of FIG. 9.

Referring to FIG. 10, the semiconductor package 200 as a fan-out type board-on-chip (BOC) package may comprise a wiring substrate 181 having a top surface 181a with the semiconductor device 150 and a bottom surface 181b with solder balls 185.

The front surface 112 of semiconductor device 150 may face the top surface 181a of the wiring substrate 181. The wiring substrate 181 may have a window 182 formed in the center, through which the chip pads 117 of the semiconductor device 150 may be exposed. Bonding wires 183 may connect the chip pads 117 of the semiconductor device 150 to the wiring substrate 181. An encapsulant 184 may seal the chip pads 117 and the bonding wires 183 for protection from external environments. The height of the solder ball 185 may be greater than the height of the encapsulant 183 for mounting the semiconductor package 200 on a motherboard.

Because the semiconductor package 200 comprises the semiconductor chip 116 having the protection layer 140 formed on the back surface 113 and the side surface 114, the semiconductor package 200 may avoid an additional process of forming an encapsulant at the back surface 113 and the side surface 114 of the semiconductor chip 116.

Thus, example embodiments of the present invention include a method for manufacturing a semiconductor device beginning with preparing a wafer having a front surface and a back surface. The wafer may have a plurality of semiconductor chips and have scribe lines provided between the semiconductor chips. The wafer may be sawn along the scribe lines at a first width to form grooves between the adjacent semiconductor chips. A protection layer may be formed on the back surface including the grooves using a screen-printing method. The wafer may be sawn along the protection layer in the grooves at a second lesser width to form individual semiconductor devices with each protection layer. The protection layer may cover a back surface and a side surface of the semiconductor chip.

The screen-printing method may be replaced with a spin coating method.

The wafer may have a tape attached to the front surface. The wafer may include a wafer that is cut along the scribe lines of the front surface at a predetermined depth.

Preparing the wafer may include attaching a tape to the front surface of the wafer and backlapping the back surface of the wafer.

The groove may be formed of sufficient width to saw the wafer along the protection layer formed therein.

The semiconductor chip may have a plurality of chip pads provided on the front surface.

The semiconductor chip may be a center pad type semiconductor chip.

The semiconductor chip may have a plurality of external connection terminals provided on the front surface.

The tape may comprise a base film and an adhesive layer provided on the base film. The adhesive layer may be formed of sufficient height to cover the external connection terminals.

The protection layer may be formed of an insulating epoxy resin or a silicon based resin. Forming the protection layer may include providing a liquid protection material on the back surface of the wafer, screen printing the liquid protection material to form the protection layer on the back surface of the wafer including the grooves, and curing the protection material.

The wafer may be sawn along the scribe lines and the protection layer in the grooves using any one of a group consisting of a sawing blade, laser and water.

Although example, non-limiting embodiments of the present invention have been described in detail hereinabove, it should be understood that many variations and/or modifications of the basic inventive concepts herein taught, which may appear to those skilled in the art, will still fall within the spirit and scope of the example embodiments of the present invention as defined in the appended claims.

What is claimed is:

1. A method for manufacturing a semiconductor device, the method comprising:
preparing a wafer having a front surface and a back surface, the wafer having a plurality of semiconductor chips;
sawing the wafer to form grooves between the semiconductor chips;
forming by screen printing a protection layer on the back surface and within the grooves; and
sawing a portion of the protection layer within the grooves to form individual semiconductor devices each with a protection layer.

2. The method of claim 1, wherein the wafer has a tape attached to the front surface.

3. The method of claim 1, wherein the wafer includes scribe lines on the front surface and the wafer is cut therealong at a predetermined depth into the front surface.

4. The method of claim 1, wherein preparing the wafer includes attaching a tape to the front surface of the wafer and backlapping the back surface of the wafer.

5. The method of claim 1, wherein the grooves are formed at a first width and wherein the step of sawing a portion of the protection layer is performed at a second width more narrow than the first width.

6. The method of claim 1, wherein each of the semiconductor chips has a plurality of chip pads provided on the front surface.

7. The method of claim 6, wherein the semiconductor chip is a center pad type semiconductor chip.

8. The method of claim 1, wherein the semiconductor chips have a plurality of external connection terminals provided on the front surface.

9. The method of claim 8, wherein preparing the wafer includes attaching a tape to the front surface of the wafer and wherein the tape comprises a base film and an adhesive layer provided on the base film and the adhesive layer is formed of sufficient height to cover the external connection terminals.

10. The method of claim 1, wherein the protection layer is formed from a liquid protection material taken from a group including an insulating epoxy resin and a silicon based resin.

11. The method of claim 10, wherein forming the protection layer includes providing the liquid protection material on the back surface of the wafer, screen printing the liquid protection material on the back surface of the wafer including the grooves, and curing the liquid protection material.

12. The method of claim 1, wherein the step of sawing the wafer and the step of sawing the protection layer each are performed by one of a group consisting of a sawing blade, laser, and water.

13. A method for manufacturing a wafer level semiconductor device, the method comprising:
preparing a wafer having a front surface and a back surface, the wafer having a plurality of semiconductor chips and scribe lines provided between the semiconductor devices;
sawing the wafer along the scribe lines to form grooves between the semiconductor chips;
forming a protection layer on the back surface and within the grooves; and
sawing a portion of the protection layer within the grooves to form individual semiconductor devices each with a protection layer.

14. The method of claim 13, wherein the groove is formed of sufficient width to subsequently saw a portion the protection layer formed therein.

15. The method of claim 13, wherein the individual semiconductor devices each have a plurality of external connection terminals provided on the front surface thereof.

16. The method of claim 15, wherein the wafer has a tape attached to the front surface, and the tape comprises a base film and an adhesive layer provided on the base film and the adhesive layer is formed of sufficient height to cover the plurality of external connection terminals.

17. The method of claim 13, wherein the step of forming the protection layer is by one of a group comprising screen-printing and spin coating.

18. A method for manufacturing a semiconductor device, the method comprising:
preparing a wafer having a front surface and a back surface, the wafer having a plurality of semiconductor chips and scribe lines provided between the adjacent semiconductor devices;
half cutting the wafer along the scribe lines of the front surface;
attaching a tape to the front surface of the wafer;
sawing the back surface of the wafer to form grooves between the adjacent semiconductor chips;
forming a protection layer on the back surface and within the grooves;
curing the protection layer;
sawing a portion of the protection layer within the grooves to form individual semiconductor devices each with a protection layer; and
separating the individual semiconductor devices from the tape.

19. The method of claim 18, wherein the grooves are formed at a first width sufficient to subsequently remove a portion of the protection layer within the grooves at a more narrow width.

20. The method of claim 19, wherein the semiconductor chips each have a plurality of external connection terminals provided on the front surface.

21. The method of claim 20, wherein the tape comprises a base film and an adhesive layer provided on the base film and the adhesive layer is sufficient to cover the external connection terminals.

22. The method of claim 18, wherein the step of forming the protection layer is by one of a group comprising screen-printing and spin coating.

23. A method of protecting a semiconductor device taken from a wafer of semiconductor devices, the method comprising:
supporting the wafer at a front surface thereof;
forming a gap of given width between semiconductor devices of the wafer to expose side surfaces of the semiconductor devices;
attaching concurrently a protective material to a backside of the wafer and the side surfaces;
removing a first portion of the protective material within the gap to leave a second portion thereof attached to the side surfaces; and
removing support of the wafer at the front surface thereof.

24. The method of protecting a semiconductor device according to claim 23, wherein the attaching step includes filling the gap with the protective material.
